(19) United States
(12) Patent Application Publication
(10) Pub. No.: US 2026/0337769 A1
(43) Pub. Date: Oct. 29, 2026

(54) ATOMIC LAYER DEPOSITION WITH IN-SITU SPUTTERING

(71) Applicant: Lam Research Corporation, Fremont, CA (US)

(72) Inventors: Jonathan Grant BAKER, King City, OR (US); Pulkit AGARWAL, Beaverton, OR (US); Pei-Chi LIU, Portland, OR (US); Gengwei JIANG, Tigard, OR (US)

(21) Appl. No.: 19/107,109

(22) PCT Filed: Aug. 22, 2023
(86) PCT No.: PCT/US2023/072609

§ 371 Date: Feb. 27, 2025

Related U.S. Application Data
(60) Provisional application No. 63/374,500, filed on Sep. 2, 2022.

(51) Int. Cl. C23C 16/455; C23C 14/34; C23C 16/04; C23C 16/44; C23C 16/505; C23C 16/52

(52) U.S. Cl. CPC C23C 16/45534; C23C 14/34; C23C 16/045; C23C 16/4408; C23C 16/4554; C23C 16/505; C23C 16/52

(57) ABSTRACT

Examples are disclosed that relate to using in-situ sputtering in an atomic layer deposition tool to form an angular surface feature in a substrate. One example provides a method of forming an angular surface feature on a substrate in an integrated circuit process. The method comprises placing the substrate in a processing chamber of an atomic layer deposition (ALD) tool. The method further comprises controlling the ALD tool to form a film on the substrate by performing one or more ALD cycles. The method further comprises controlling the ALD tool to sputter the film to form the angular surface feature.

### BACKGROUND

Electronic device fabrication processes may involve many steps of material deposition, patterning, and removal to form integrated circuits on substrates. Various methods can be used to process films of materials to form integrated circuits. For example, atomic layer deposition (ALD) can be used to form a film on a substrate in a layer-by-layer manner. As another example, sputtering may be performed to remove material from a substrate by impacting the substrate with gas-phase ions.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to using in-situ sputtering in an atomic layer deposition tool to form an angular surface feature in a substrate in an ALD deposition process. One example provides a method of forming an angular surface feature on a substrate. The method comprises placing the substrate in a processing chamber of an atomic layer deposition (ALD) tool. The method further comprises controlling the ALD tool to form a film on the substrate by performing one or more ALD cycles. The method further comprises controlling the ALD tool to sputter the film to form the angular surface feature.

In some such examples, an ALD cycle of the one or more ALD cycles comprises introducing a film precursor into the processing chamber to adsorb the film precursor on the substrate, purging the processing chamber, introducing a reactant into the processing chamber, and reacting the film precursor and the reactant by forming a plasma comprising the reactant to form the film.

In some such examples, controlling the ALD tool to sputter the film additionally or alternatively comprises sputtering the film within the ALD cycle using ions in the plasma.

In some such examples, the method additionally or alternatively further comprises controlling the ALD tool to form the plasma using a lower frequency component and a higher frequency component.

In some such examples, controlling the ALD tool to sputter the film additionally or alternatively comprises performing a sputtering cycle in the ALD tool separate from the one or more ALD cycles.

In some such examples, the angular surface feature additionally or alternatively comprises a dent above a void.

In some such examples, the angular surface feature additionally or alternatively comprises a bevel in a liner of a gap.

In some such examples, controlling the ALD tool to sputter the film additionally or alternatively comprises forming a plasma comprising an inert gas and hydrogen.

In some such examples, controlling the ALD tool to sputter the film additionally or alternatively comprises controlling the processing tool to heat a substrate heater to a temperature within a range of 50 °C to 1000 °C.

In some such examples, controlling the ALD tool to sputter the film additionally or alternatively comprises controlling the ALD tool to maintain a pressure of 8 Torr or lower in the processing chamber during sputtering.

Another example provides an atomic layer deposition (ALD) tool. The ALD tool comprises a processing chamber. The ALD tool further comprises a substrate support disposed in the processing chamber. The ALD tool further comprises a film precursor source comprising a film precursor. The ALD tool further comprises a reactant gas source comprising a reactant. The ALD tool further comprises an inert gas source comprising an inert gas. The ALD tool further comprises flow control hardware configured to control flows of film precursor, reactant, and inert gas into the processing chamber. The ALD tool further comprises a radiofrequency power source operable to form a plasma in the processing chamber. The ALD tool further comprises a controller configured to control the flow control hardware and the radiofrequency power source to perform one or more ALD cycles to form a film on a substrate placed on the substrate support. The controller is further configured to control the flow control hardware and the radiofrequency power source to perform one or more sputtering cycles to sputter the film to form an angular surface feature, the one or more sputtering cycles being separate from the one or more ALD cycles.

In some such examples, the ALD tool further comprises a hydrogen gas source comprising hydrogen gas, and the controller is further configured to control the flow control hardware to introduce the inert gas and the hydrogen gas into the processing chamber, and control the radiofrequency power source to form a plasma comprising the inert gas and the hydrogen gas.

In some such examples, the radiofrequency power source additionally or alternatively is configured to supply radiofrequency power comprising a lower frequency component and a higher frequency component.

In some such examples, the ALD tool additionally or alternatively further comprises an exhaust system, and the controller is further configured to control the flow control hardware and the exhaust system to maintain a pressure inside the processing chamber of 8 Torr or lower during the one or more sputtering cycles.

In some such examples, the controller additionally or alternatively is further configured to sputter the film during at least one ALD cycle of the one or more ALD cycles.

In some such examples, the ALD tool additionally or alternatively further comprises a substrate heater, and the controller is configured to heat the substrate heater to a temperature within a range of 50 °C to 1000 °C.

In some such examples, the controller additionally or alternatively is further configured to purge the chamber after controlling the radiofrequency power source to extinguish the plasma.

In some such examples, the flow control hardware additionally or alternatively is configured to introduce the inert gas into the processing chamber through a processing chemical outlet, the processing chemical outlet being separated from the substrate by a spacing within a range of 0.2 inches to 0.8 inches.

Another example provides an atomic layer deposition (ALD) tool comprising a processing chamber. The ALD tool further comprises a substrate support disposed in the processing chamber. The ALD tool further comprises one or more film precursor sources comprising one or more film precursors. The ALD tool further comprises an inert gas source comprising an inert gas. The ALD tool further comprises one or more reactant sources comprising one or more reactants. The ALD tool further comprises flow control hardware configured to control flows of the one or more film precursors, the one or more reactants, and the inert gas into the processing chamber. The ALD tool further comprises a radiofrequency power source and an electrode pair configured to form a plasma in the processing chamber. The ALD tool further comprises a controller configured to control the flow control hardware and the radiofrequency power source to perform one or more ALD cycles with sputtering to form a film on a substrate placed on the substrate support and to form an angular surface feature of the film.

In some such examples, the one or more reactants comprises a nitrogen-containing precursor.

In some such examples, the one or more reactants additionally or alternatively comprises an oxidant.

### BRIEF DESCRIPTION OF THE DRAWINGS

FIGS. 1A-1B show an example ALD gap fill process without in-situ sputtering.

FIG. 2 shows a block diagram of an example ALD tool.

FIGS. 3A-3B show an example ALD gap fill process that utilizes in-situ sputtering.

FIG. 4 shows an example ALD liner deposition process that omits in-situ sputtering.

FIGS. 5A-5C show an example ALD liner deposition process that utilizes in-situ sputtering to form an example angular surface feature.

FIGS. 6A-6C show another example ALD liner deposition process that utilizes in-situ sputtering to form an example angular surface feature.

FIG. 7 shows a flow diagram depicting an example method for performing in-situ sputtering concurrently with an atomic layer deposition (ALD) cycle.

FIG. 8 shows a flow diagram depicting an example method for performing separate ALD cycles and in-situ sputtering cycles.

FIG. 9 shows a flow diagram depicting an example method for performing ALD cycles with or without sputtering, in addition to separate in-situ sputtering cycles.

FIG. 10 shows a block diagram of an example computing device.

### DETAILED DESCRIPTION

The term “atomic layer deposition” (ALD) may generally represent a process in which a film is formed on a substrate in individual film layers by sequential ALD cycles. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth”, “deposition”, and variants thereof, also may be used to refer to film formation.

The term “ALD cycle” may generally represent a cycle of adsorbing a precursor to the substrate and reacting the adsorbed precursor to form a film layer.

The term “ALD cycle with sputtering” may generally represent an ALD cycle in which a film layer is formed using a plasma configured to cause controllable in-situ sputtering of an angular surface feature of the film.

The term “ALD cycle without sputtering” may generally represent a PEALD or other ALD cycle in which a film layer is formed using a plasma configured not to cause in-situ sputtering of an angular surface feature of the film.

The term “ALD tool” may generally represent a machine comprising a processing chamber and other hardware configured to enable ALD to be carried out in the processing chamber.

The term “angular surface feature” may generally represent a feature on a substrate surface that is transverse both to a plane of the substrate surface and to a substrate surface normal. Example angular surface features may include dents and bevels. When used in reference to an angular surface feature, the term “profile” may generally represent a cross-sectional shape of the angular surface feature.

The term “bevel” may generally represent an angled edge of a feature.

The term “bevel angle” may generally be used to refer to an angle of a bevel relative to a substrate surface.

The term “dent” may generally represent an angular surface feature that is recessed from a substrate surface. A dent may be formed over a gap during a gap fill process. In various examples, the sides of a dent may be substantially flat or curved.

The term “dent angle” may generally be used to refer to an angle between dent sides.

The term “film” may generally represent a layer of material deposited on a substrate.

The term “film precursor” may generally represent a chemical that can be adsorbed to a substrate surface and be chemically transformed to form a film. The chemical transformation may occur by reaction with a reactant. Example films include films of silicon oxide, silicon nitride, silicon oxynitride, silicon carbide, silicon oxycarbide, and metal oxides such as aluminum oxide, molybdenum oxide, titanium oxide, tungsten oxide, tin oxide, zirconium oxide, or hafnium oxide. Example film precursors include silicon-containing precursors, carbon-containing precursors, and metal-containing precursors such as molybdenum-containing precursors, tungsten-containing precursors, aluminum-containing precursors, titanium-containing precursors, tin-containing precursors, zirconium-containing precursors, and hafnium-containing precursors.

Example silicon-containing precursors for forming silicon-containing films using ALD may comprise materials having the general structure:

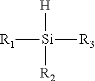

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups.

More specific example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that may be used include the following: Hₓ—Si—(OR)_{y}, where x=1-3, x+y=4 and each R is a substituted or unsubstituted alkyl, substituted or unsubstituted alkenyl, substituted or unsubstituted alkynyl, or substituted or unsubstituted aromatic group; and Hₓ(RO)_{y}, —Si—Si—(OR)_{y}Hₓ, where each R is a substituted or unsubstituted alkyl, substituted or unsubstituted alkenyl, substituted or unsubstituted alkynyl, or substituted or unsubstituted aromatic group.

Further examples of silicon-containing precursors include tetraethyl orthosilicate (TEOS), tetramethoxysilane (TMOS), methylsilane, trimethylsilane (3MS), tetramethylsilane, ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

Further, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino) silane (3DMAS). Aminosilane precursors include the following: Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group.

In some examples, a halogen-containing silane may be used as a silicon-containing precursor such that the silane includes at least one hydrogen atom. Such a silane may have a chemical formula of SiXₐH_{y} where y≥1, a+y=4. Dichlorosilane (H₂SiCl₂) may be used in some examples.

Example carbon-containing film precursors for forming a silicon carbide film include alkanes having a general formula CₙH₂ₙ₊₂ where n=1 to 10 (such as, methane, ethane, etc.), alkenes having a general formula CₙH₂ₙ where n=2 to 10 (such as, ethylene, propylene, etc.), alkynes having a general formula CₙH₂ₙ₋₂ where n=2 to 10 (such as, acetylene, propyne, etc.), and other hydrocarbons (such as cyclic hydrocarbons and nitrogen-containing compounds, including aromatic compounds), that are in gaseous phase under processing conditions.

The term “metal-containing precursor” may generally represent any material that can be introduced into a processing chamber and oxidized on a substrate surface to form a metal oxide film on the substrate surface. Examples of metal-containing precursors include aluminum-containing precursors, molybdenum-containing precursors, titanium-containing precursors, tungsten-containing precursors, tin-containing precursors, zirconium-containing precursors and hafnium-containing precursors which respectively may be used to form aluminum oxide (AlOₓ), molybdenum oxide (MoOₓ), titanium oxide (TiOₓ), tungsten oxide (WOₓ) films, tin oxide (SnOₓ) films, zirconium oxide (ZrOₓ) films, and hafnium oxide (HfOₓ) films.

Examples of aluminum-containing precursors for forming aluminum oxide (AlOₓ) include aluminum halides (AlX_{y}), aluminum alkoxide (C₉H₂₁AlO₃), trimethyl aluminum (AlC₃H₉), aluminum carbonyl (Al(CO)ₓ), and aluminum hydride (AlH₃).

Examples of molybdenum-containing precursors for forming molybdenum oxide (MoOₓ) include bis(tert-butylimino)bis(dimethylamino) molybdenum (C₁₂H₃₀MoN₄), molybdenum pentachloride (MoCl₅), molybdenum dioxide dichloride (MoO₂Cl₂), molybdenum oxytetrachloride (MoOCl₄) and molybdenum hexacarbonyl (Mo(CO)₆).

Examples of titanium-containing precursors for forming titanium oxide films (TiOₓ) include titanium tetrachloride (TCl₄) and titanium isopropoxide (Ti(OCH(CH₃)₂)₄).

Examples of tungsten-containing precursors for forming tungsten oxide films (WOₓ) include tungsten hexafluoride (WF₆), tungsten hexachloride (WCl₆), bis(tert-butylimino)bis(dimethylamino) tungsten (C₁₂H₃₀N₄W) and tungsten hexacarbonyl (W(CO)₆).

Examples of tin-containing precursors for forming tin oxide films (SnOₓ) include tin tetrachloride (SnCl₄), tetramethyltin ((CH₃)₄Sn), tetraethyltin ((C₂H₅)₄Sn), dimethyltin dichloride ((CH₃)₂SnCl₂), dibutyl (dimethoxy) stannane (Bu₂Sn(OMe)₂), tetrakis(dimethylamido)tin(IV) (Sn(NMe₂)₄), dimethylamino dimethyl tin (Me₂Sn(NMe₂)₂), and dimethylamino trimethyl tin (Me₃Sn(NMe₂)), where Bu represents a butyl group (C₄H₉) and Me represents a methyl group (CH₃).

Examples of zirconium-containing precursors tetrakis(dimethylamido) zirconium(IV) ((NMe₂)₄Zr), tetrakis(ethylmethylamido) zirconium(IV) (((NEtMe)₄Zr), and tetrakis(diethylamido) zirconium(IV) ((NEt₂)₄Zr), where Et represents an ethyl group (C₂H₅).

Examples of hafnium-containing precursors for forming hafnium oxide films (HfOₓ) include hafnium tetrachloride (HfCl₄), tetrakis(diethylamino) hafnium (Hf(N(C₂H₅)₂)₄), and tetrakis(tert-butoxide) hafnium (Hf(OC(CH₃)₃)₄).

Example reactants that may react with a film precursor to form a film may comprise oxidants and nitrogen-contributing compounds. Example oxidants include oxygen, ozone, hydrogen peroxide, and water vapor. Example reactants for contributing nitrogen for formation of a silicon nitride film include nitrogen (N₂), ammonia (NH₃) and hydrazine (N₂H₄). An example reactant for providing nitrogen for formation of a silicon oxynitride film is N₂O.

The term “flow control hardware” may generally represent components configured to place one or more chemical sources in fluid connection with a processing chamber. Flow control hardware may comprise one or more mass flow controllers and/or valves, for example. Example chemical sources include film precursor sources, inert gas sources, and reactant gas sources.

The term “gap” may generally represent a recessed feature in a substrate surface.

The term “gap fill” may generally represent a process that at least partially fills a gap on a substrate with a material.

The term “intermediate structure” may generally represent a structure formed by earlier processing steps that is modified in later processing steps.

The term “liner” may generally represent a film of material that coats a substrate feature.

The term “plasma” may generally represent an ionized gas comprising positive ions and free electrons. Plasmas may be generated using any suitable method and may include radiofrequency (RF) plasmas, microwave plasmas, and electron beam generated plasmas. A plasma may be used to generate radical species.

The term “processing chamber” may generally represent an enclosure in which chemical and/or physical processes are performed on substrates.

The term “processing chemical outlet” may generally represent any structure for injecting a gas-phase processing chemical into a processing chamber of a processing tool. A processing chemical outlet may comprise a nozzle or showerhead in various examples. Example processing chemicals include film precursors, reactants, and inert gases.

The term “processing tool” may generally represent a machine comprising a processing chamber and other hardware configured to enable processing to be carried out in the processing chamber.

The term “purge” and variants thereof may generally represent processes in which unwanted species are removed from a processing chamber.

The term “radiofrequency (RF) power source” may generally represent a component of a processing tool configured to apply power to a pair of electrodes in a processing chamber to form a plasma between the electrodes.

The term “showerhead” may generally represent a processing chemical outlet comprising a plurality of holes distributed across an area.

The term “sputtering” and variants thereof may generally represent processes in which ions in a plasma are accelerated toward a substrate with sufficient kinetic energy to cause at least some material to be ejected from the substrate upon collision with the substrate. “In-situ sputtering” refers to sputtering that is performed within an ALD tool.

The term “sputtering cycle” may generally represent a process cycle comprising sputtering a substrate surface using ions in a plasma.

The term “substrate” may generally represent any object on which a film can be deposited.

The term “substrate heater” may generally represent a heater in a processing chamber configured to heat a substrate.

The term “substrate support” may generally represent any structure for supporting a substrate in a processing chamber. Examples comprise chucks, pedestals, and showerhead pedestals used for backside deposition processes.

The term “sticking coefficient” may generally represent a ratio of a number of gas-phase species that adsorb to a substrate surface compared to a number of the gas-phase species that impinge upon the substrate surface.

The term “void” may generally represent a hollow cavity in a substrate.

The term “3D DRAM” is an acronym for three-dimensional dynamic random-access memory.

The term “3D NAND” is an acronym for three-dimensional NOT AND memory, and represents memory architecture based upon NOT AND logic gates.

The term “3D NOR” is an acronym for three-dimensional NOT OR memory, and represents memory architecture based upon NOT OR logic gates.

As mentioned above, the fabrication of electronic devices involves many steps of material deposition, patterning, and removal. For example, 3D NAND (Not AND) semiconductor devices are built upon stacked pairs of material layers. One layer per pair is a device layer. The other layer per pair is a dielectric layer for electrical isolation. A stack comprising a plurality of such pairs of material layers may be referred to as a “mold stack”. Patterning, etch, and metallization of the mold stack is performed to create a 3D NAND memory chip. Similar processes may be used to form 3D DRAM and 3D NOR chips.

During 3D NAND device integration flow, large regions are created within the device that are effectively empty space. These regions are referred to as gaps. These gaps can be filled with material to provide material for further patterning steps and/or for forming various structures such as circuits, gates, or memory structures.

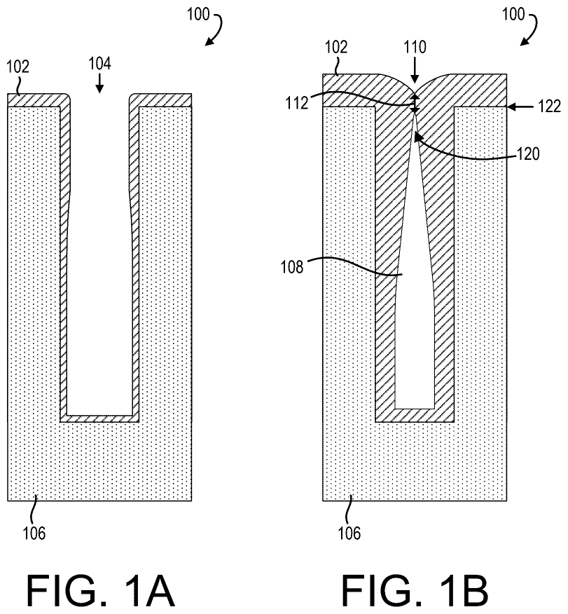

In some examples, a gap is partially filled to create a void to achieve desired electronic properties and/or mechanical properties. For example, when forming 3D NAND memory blocks, ALD can be used to deposit material in a gap such that deposited material forms a void between memory blocks. FIGS. 1A-1B schematically show an example of such a deposition process. FIG. 1A shows an intermediate structure comprising a film 102 that is partially deposited in a process to fill a gap 104 in a substrate 106. In some examples, the profile of the void and/or the film thickness may be tunable by adjusting processing conditions. Substrate 106 may represent a 3D NAND mold stack in some examples. In other examples, substrate 106 may represent any other suitable structure, such as an intermediate structure in a 3D DRAM or 3D NOR process. Film 102 may comprise any suitable material. Examples include silicon oxide, silicon nitride, and silicon oxynitride.

As the film 102 grows, the sticking coefficient of the material forming film 102 causes film 102 to preferentially deposit closer to an opening of gap 104 than deeper within gap 104. As such, referring next to FIG. 1B, film 102 pinches off gap 104 near the top of gap 104 to form a void 108. Further, a dent 110 forms above void 108 at the surface of film 102.

The dent 110 formed above void 108 may have a sharp angle where the sides of dent 110 meet. A dent 110 with a sharp angle may lead to formation of an additional, and undesirable, void (not shown) when dent 110 is covered with another material. Furthermore, an upper end 120 of void 108 is located near the substrate surface, close to dent 110. As such, film 102 has a relatively thin profile. This is indicated by thickness 112. In some examples, void 108 may be less than 40 nm from dent 110. In some examples, upper end 120 of void 108 may be above a top surface 122 of substrate 106. This may lead to void 108 being opened when planarizing or etching in subsequent processing. Such issues may lead to device defects.

One possible solution is to use an ALD tool to deposit a portion of film 102, and then move the substrate to a sputtering tool for modification of the deposited film. For example, sputtering may be used to move material of film 102 to locations deeper within gap 104. Alternating ALD cycles and sputtering cycles alternatively or additionally may be used to drive a pinch-off location of film 102 deeper into gap 104. However, moving a substrate between an ALD tool and a sputtering tool may be time-consuming, add cost, and lower throughput.

Accordingly, examples are disclosed that relate to performing in-situ sputtering within an ALD tool. In-situ sputtering within an ALD tool may be performed to modify the profile of an angular surface feature of a film, such as dent 110, during film deposition. Performing in-situ sputtering and film deposition in an ALD tool be used to partially fill a gap while avoiding the formation of a sharp dent angle. In-situ sputtering during ALD deposition also may be used to move a pinch-off depth of the film deeper within the gap compared to ALD without in-situ sputtering. Performing in-situ sputtering in an ALD tool also may allow other angular surface features to be formed. Another example of an angular surface feature comprises a beveled liner formed within a gap. As described in more detail below, such structures may be formed without moving a substrate repeatedly between an ALD tool and a sputtering tool. This may allow angular surface features to be efficiently formed during a film deposition process by in-situ sputtering in an ALD tool.

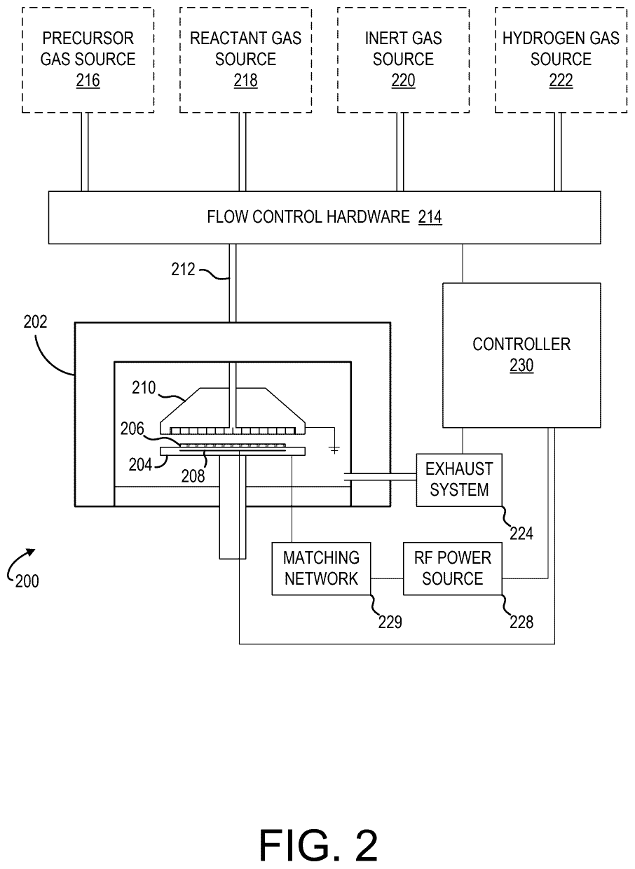

FIG. 2 schematically shows an example ALD tool 200 configured to perform in-situ sputtering. ALD tool 200 is configured as a PEALD tool. ALD tool 200 comprises a processing chamber 202 and a substrate support 204 within the processing chamber. Substrate support 204 is configured to support a substrate 206 disposed within processing chamber 202. Substrate support 204 may comprise a pedestal, a chuck, and/or any other suitable structure. Substrate support 204 is configured to be raised and lowered to adjust the position of substrate 206 within processing chamber 202.

Processing chamber 202 further may include a substrate heater 208 configured to heat a substrate placed on substrate support 204. In other examples, a heater may be omitted. In some examples, substrate heater 208 is configured to heat to a temperature within a range of 50 °C to 1000 °C. In some examples, a relatively higher substrate temperature may be used to achieve a relatively greater degree of sputtering.

ALD tool 200 further comprises a processing chemical outlet 210 and flow control hardware 214. In some examples, processing chemical outlet 210 may comprise a nozzle, showerhead, or other apparatus for introducing gas into processing chamber 202. Substrate support 204 can be raised and lowered to adjust the spacing between substrate 206 and processing chemical outlet 210. In some examples, the spacing may be adjusted to a spacing within a range of 0.2 inches to 0.8 inches. In other examples, a spacing outside this range may be used. In some examples, a relatively smaller spacing may provide a greater sputtering rate compared to a larger spacing.

Flow control hardware 214 is connected to a film precursor source 216, a reactant gas source 218, an inert gas source 220, and an optional hydrogen-containing gas source 222. Film precursor source 216 may comprise any suitable film precursor that may form a film in an ALD process. Example films include films of silicon oxide, silicon nitride, silicon oxynitride, silicon carbides, silicon oxycarbides, and metal oxides such as aluminum oxide, molybdenum oxide, titanium oxide, tungsten oxide, tin oxide, zirconium oxide, or hafnium oxide.

Example silicon-containing precursors for forming silicon-containing films using ALD may comprise materials having the general structure:

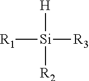

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups.

More specific example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that may be used include the following: Hₓ—Si—(OR)_{y}, where x=1-3, x+y=4 and each R is a substituted or unsubstituted alkyl, substituted or unsubstituted alkenyl, substituted or unsubstituted alkynyl or substituted or unsubstituted aromatic group; and Hₓ(RO)_{y}, —Si—Si—(OR)_{y}Hₓ, where R is a substituted or unsubstituted alkyl, substituted or unsubstituted alkenyl, substituted or unsubstituted alkynyl or substituted or unsubstituted aromatic group.

Further examples of silicon-containing precursors include tetraethyl orthosilicate (TEOS), tetramethoxysilane (TMOS), methylsilane, trimethylsilane (3MS), tetramethylsilane, ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

Further, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino) silane (3DMAS). Aminosilane precursors include the following: Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group.

In some examples, a halogen-containing silane may be used such that the silane includes at least one hydrogen atom. Such a silane may have a chemical formula of SiXₐH_{y} where y≥1, a+y=4. Dichlorosilane (H₂SiCl₂) may be used in some examples.

Example carbon-containing precursors for forming a silicon carbide film include alkanes having a general formula CₙH₂ₙ₊₂ where n=1 to 10 (such as methane, ethane, etc.), alkenes having a general formula CₙH₂ₙ where n=2 to 10 (such as ethylene, propylene, etc.), alkynes having a general formula CₙH₂ₙ₋₂ where n=2 to 10 (such as acetylene, propyne, etc.), and other hydrocarbons (such as aromatics and other cyclic hydrocarbons, and nitrogen-containing compounds), that are in gaseous phase under processing conditions.

Examples of aluminum-containing precursors for forming aluminum oxide (AlOₓ) include aluminum halides (AlX_{y}), aluminum alkoxide (C₉H₂₁AlO₃), trimethyl aluminum (AlC₃H₉), aluminum carbonyl (Al(CO)ₓ), and aluminum hydride (AlH₃).

Examples of molybdenum-containing precursors for forming molybdenum oxide (MoOₓ) include bis(tert-butylimino)bis(dimethylamino) molybdenum (C₁₂H₃₀MoN₄), molybdenum pentachloride (MoCl₅), molybdenum dioxide dichloride (MoCl₅), molybdenum oxytetrachloride (MoOCl₄) and molybdenum hexacarbonyl (Mo(CO)₆).

Examples of titanium-containing precursors for forming titanium oxide films (TiOₓ) include titanium tetrachloride (TCl₄) and titanium isopropoxide (Ti(OCH(CH₃)₂)₄).

Examples of tungsten-containing precursors for forming tungsten oxide films (WOₓ) include tungsten hexafluoride (WF₆), tungsten hexachloride (WCl₆), bis(tert-butylimino)bis(dimethylamino) tungsten (C₁₂H₃₀N₄W) and tungsten hexacarbonyl (W(CO)₆).

Examples of tin-containing precursors for forming tin oxide films (SnOₓ) include tin tetrachloride (SnCl₄), tetramethyltin ((CH₃)₄Sn), tetraethyltin ((C₂H₅)₄Sn), dimethyltin dichloride ((CH₃)₂SnCl₂), dibutyl (dimethoxy) stannane (Bu₂Sn(OMe)₂), tetrakis(dimethylamido)tin(IV) (Sn(NMe₂)₄), dimethylamino dimethyl tin (Me₂Sn(NMe₂)₂), and dimethylamino trimethyl tin (Me₃Sn(NMe₂)).

Examples of zirconium-containing precursors tetrakis(dimethylamido) zirconium(IV) ((NMe₂)₄Zr), tetrakis(ethylmethylamido) zirconium(IV) (((NEtMe)₄Zr), and tetrakis(diethylamido) zirconium(IV) ((NEt₂)₄Zr).

Examples of hafnium-containing precursors for forming hafnium oxide films (HfOₓ) include hafnium tetrachloride (HfCl₄), tetrakis(diethylamino) hafnium (Hf(N(C₂H₅)₂)₄), and tetrakis(tert-butoxide) hafnium (Hf(OC(CH₃)₃)₄).

Reactant gas source 218 may comprise any suitable reactant or mixture of reactants that, when reacted with a film precursor adsorbed to a substrate surface, forms a film. Example reactants providing oxygen for the formation of oxide films include oxygen gas (O₂), hydrogen peroxide (H₂O₂), ozone (O₃), and water vapor (H₂O). Example reactants for providing nitrogen for formation of a silicon nitride film include nitrogen (N₂), ammonia (NH₃) and hydrazine (N₂H₄). An example reactant for providing nitrogen and oxygens for formation of a silicon oxynitride film is N₂O. When an oxycarbide film is being deposited, one or more reactant gas sources may comprise an oxidant and a carbon-containing species.

Inert gas source 220 may comprise any suitable inert gas. Examples include one or more of argon, nitrogen, helium, neon, krypton, or xenon. The inert gas can be used to form a plasma to sputter a film. In some examples, a heavier inert gas may provide for a higher rate of sputtering compared to a lighter gas. For example, argon may provide a relatively greater sputtering rate compared to helium in similar pressure, temperature, and RF power conditions.

Hydrogen-containing gas source 222 comprises any suitable hydrogen-containing gas. Examples include one or more of hydrogen gas, ammonia, water, methane, or silane. Introducing a hydrogen-containing gas into the processing chamber may enhance sputtering of a film. For example, the presence of hydrogen in the processing chamber during sputtering may help to chemically reduce a surface of a film and/or passivate dangling bonds on the surface of the film. Passivation of dangling bonds may facilitate the ejection of film material by kinetic ions during sputtering.

Flow control hardware 214 may be controlled to flow gas from film precursor source 216, reactant gas source 218, inert gas source 220, and hydrogen-containing gas source 222 into processing chamber 202 via processing chemical outlet 210. Flow control hardware 214 may comprise one or more mass flow controllers and/or valves controllable to place one or more selected gas sources in fluid connection with processing chemical outlet 210. In other examples, a processing tool may comprise one or more additional processing chemical outlets than processing chemical outlet 210.

ALD tool 200 further comprises an exhaust system 224. Exhaust system 224 is configured to exhaust gases from processing chamber 202. Exhaust system 224 may comprise one or pumps. In some examples, exhaust system 224 is configured to actively remove gas from processing chamber 202 and/or apply a partial vacuum. As such, flow control hardware 214 and exhaust system 224 can be used to control the pressure inside processing chamber 202. In some examples, the pressure may be adjusted to 8 torr or below. In some examples, a relatively lower pressure may provide more efficient sputtering compared to a relatively higher pressure. In some examples, ALD tool 200 is configured to apply a relatively lower pressure during a sputtering cycle and apply a relatively higher pressure during an ALD cycle.

ALD tool 200 further comprises a radiofrequency power source 228 that is electrically connected to substrate support 204. Radiofrequency power source 228 is configured to form a plasma comprising the inert gas and/or the reactant. In some examples, the plasma may further comprise hydrogen. Processing chemical outlet 210 is configured as a grounded opposing electrode in this example. In other examples, radiofrequency power source 228 may supply radiofrequency power to processing chemical outlet 210, or to other suitable electrode structure. ALD tool 200 further includes a matching network 229 for impedance matching of the radiofrequency power source 228. Radiofrequency power source 228 may be configured for any suitable frequency and power (i.e., amplitude). Examples of suitable frequencies include 400 kHz, 13.56 MHz, 27 MHz, 60 Mz, and 90 MHz. Examples of suitable powers include powers between 0 and 1500 watts. In some examples, radiofrequency power source 228 is configured to operate at a plurality of different frequencies and/or powers. In some examples, a first, higher frequency RF power component may be used to form a plasma and a second, lower frequency RF power component may be used to enhance in-situ sputtering. For example, use of RF power with a higher amplitude may provide a relatively greater sputtering rate compared to a lower amplitude. Furthermore, use of a high frequency RF power component in combination with a low frequency RF power component may provide a relatively greater sputtering rate compared to examples that omit a low frequency RF power component.

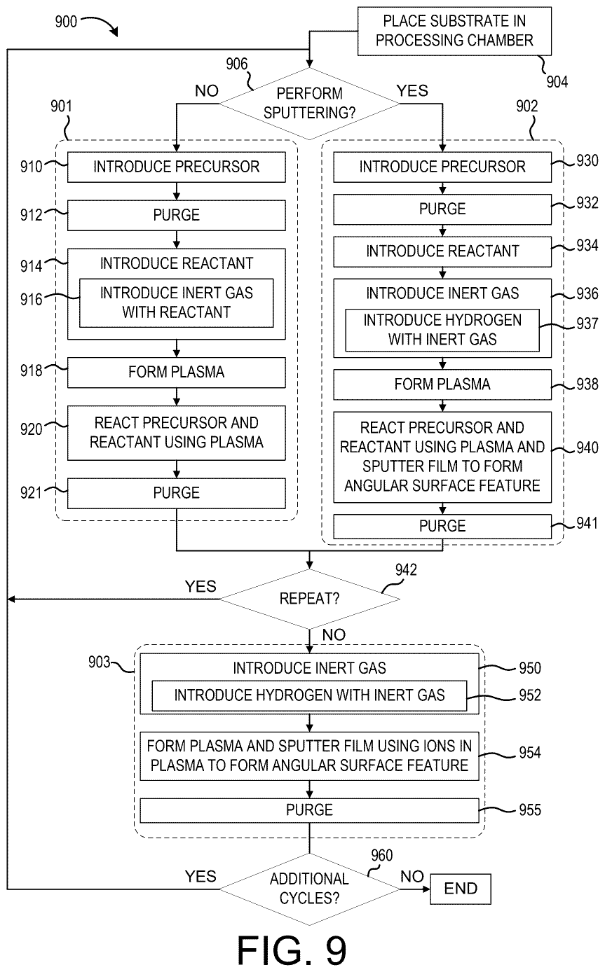

Controller 230 is operatively coupled to substrate heater 208, flow control hardware 214, exhaust system 224, and radiofrequency power source 228. Controller 230 is configured to control various functions of ALD tool 200 to perform ALD cycles with sputtering, ALD cycles without sputtering, and/or sputtering cycles to form an angular surface feature on a substrate. Example process cycles for performing ALD deposition comprising in-situ sputtering are described in more detail below. For example, controller 230 is configured to operate substrate heater 208 to heat the substrate heater to a selected temperature. Controller 230 is also configured to raise and lower substrate support 204 to adjust the spacing between substrate 206 and processing chemical outlet 210. Controller 230 is also configured to operate flow control hardware 214 to flow a selected gas or mixture of gases at a selected rate into processing chamber 202. Controller 230 is further configured to operate exhaust system 224 to remove gases from processing chamber 202. Controller 230 is further configured to operate flow control hardware 214 and exhaust system 224 to control a pressure inside processing chamber 202. Furthermore, controller 230 is configured to operate radiofrequency power source 228 to form a plasma to react one or more film precursors to form a film. Controller 230 is also configured to operate radiofrequency power source 228 to form a plasma to perform sputtering on the film, as well as to control any other suitable functions of ALD tool 200. Controller 230 may comprise any suitable computing system, examples of which are described below with reference to FIG. 9.

As discussed above with regard to FIGS. 1A and 1B, a sticking coefficient of a film precursor may result in a film preferentially growing closer to an opening of a gap compared to deeper within a gap in a gap fill process. The preferential growth may result in a relatively thin film above a void formed by the gap fill process. The preferential growth also may result in a relatively sharp dent angle in the film above the void. Thus, an ALD process comprising in-situ sputtering may be used to overcome these problems.

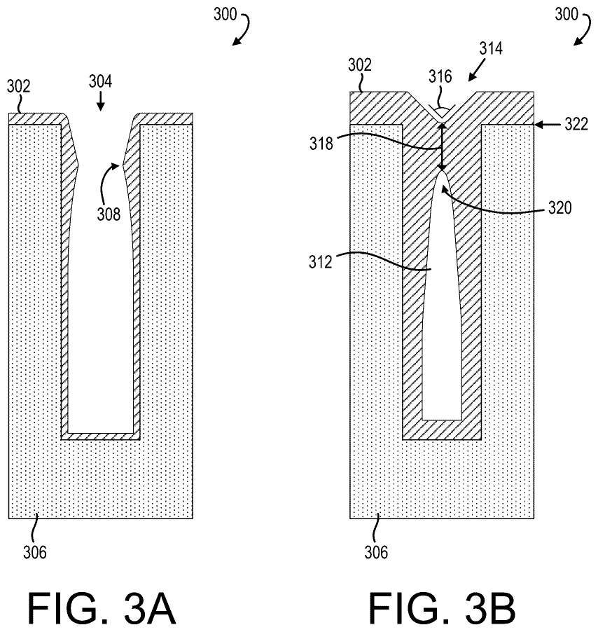

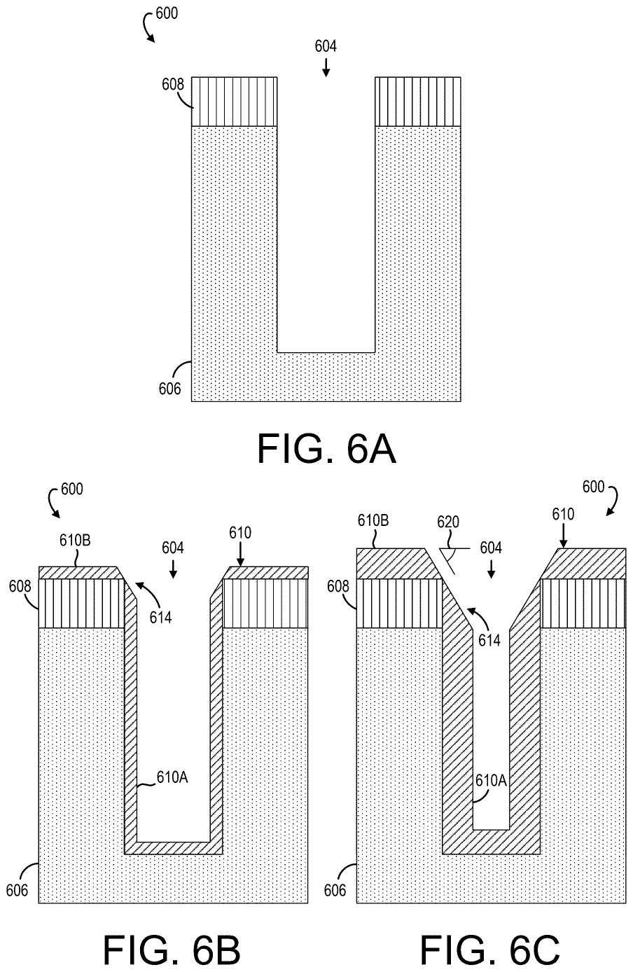

FIGS. 3A-3B schematically show an example ALD process that utilizes sputtering to form a void in a gap and control a profile of a dent above the void. Referring first to FIG. 3A, an intermediate structure 300 is shown that comprises a film 302 being deposited within a gap 304 of a substrate 306 using ALD. Film 302 may comprise any suitable film. Examples include films of silicon oxide, silicon nitride, silicon oxynitride, silicon carbides, silicon oxycarbides, and metal oxides such as aluminum oxide, molybdenum oxide, titanium oxide, tungsten oxide, tin oxide, zirconium oxide, or hafnium oxide. During ALD deposition of film 302, processing conditions are controlled to cause in-situ sputtering of film 302. Sputtering may eject material from film 302 near the opening of gap 304. The ejected film material may be redeposited deeper in gap 304, forming a cusp 308. Various example process cycles that include ALD deposition with in-situ sputtering are described with regard to FIGS. 6-8 below.

FIG. 3B shows intermediate structure 300 after further film deposition. As ALD proceeds, cusp 308 pinches off to form a void 312. A profile of void 312 can be tuned by controlling processing conditions. Further, a dent 314 is positioned above void 312. Dent 314 is an angular surface feature comprising a profile with a dent angle 316. Due to in-situ sputtering during ALD, dent angle 316 may be relatively wider compared to dent 110 of FIG. 1B. In some examples, dent angle 316 comprises an angle between 60° and 120°. Further, in some examples, a final sputtering cycle after completion of ALD film deposition may be used to modify the dent angle and/or achieve a selected dent depth. For example, a final sputtering cycle may be used to increase the dent angle to ≥80°, ≥90°, or ≥95°. In other examples, a dent angle may be outside these ranges. In addition to a wider dent angle, the bottom of dent 314 may become rounder due to sputtering. A wider dent angle and/or a rounder dent may facilitate further processing of a substrate. For example, in contrast to the relatively sharp angle of dent 110 (FIG. 1B), it may be easier to avoid forming an unwanted void when depositing material on top of dent 314 in subsequent processing steps.

Further, sputtered material redeposits deeper in gap 304 to form cusp 308. As such, the closure depth of void 312 is pushed deeper within gap 304 compared to performing the ALD deposition without sputtering of FIGS. 1A-1B. Thus, thickness 318 is greater than thickness 112. Further, a distance between upper end 320 of void 312 and top surface 322 of substrate 306 is greater than a distance between upper end 120 and top surface 122 of FIGS. 1A-1B. In some examples, thickness 318 may be within a range of 10 to 1000 nm. In other examples, thickness 318 may have a suitable value outside of this range. Thickness 318 may depend upon a width of gap 304. In some examples, thickness 318 is dependent upon the width of gap 304. Thickness 318 may help to avoid opening void 312 in subsequent processing steps. For example, etching and/or planarization processes performed on structure 100 of FIG. 1B may cause the void to be punctured or lead to cracks in film 102 film. In contrast, structure 300 comprises a thicker portion above void 312, and upper end 320 is below top surface 322. Thus, film 302 may be less likely to crack or puncture. In various examples, the profile, size, and position of a void is tunable according to processing conditions.

In-situ sputtering also may help achieve a rounder profile at the top of the void compared to examples that omit sputtering. For example, the upper end 120 (FIG. 1B) of void 108 (FIG. 1B) has a relatively sharper profile compared to the upper end 320 of void 312, which is more rounded. A rounded profile may help spread stress compared to a sharper profile. Thus, the more rounded profile of upper end 320 of void 312 may provide a more mechanically robust film than upper end 120 (FIG. 1B) of void 108 (FIG. 1B).

In-situ sputtering during ALD may be implemented using any suitable processes. In some examples, an ALD process may comprise performing in-situ sputtering during film deposition. In other examples, an ALD process may comprise performing in-situ sputtering separately from deposition. In yet other examples, a mix of sputtering during deposition and sputtering separately from deposition may be used. Example ALD processes comprising in-situ sputtering are described in more detail below.

Various processing conditions may be controlled to control a degree of in-situ sputtering. As one example, a higher amplitude RF power may be used to cause a higher rate of in-situ sputtering during deposition. Likewise, a lower amplitude RF power may be used to cause a lower rate of in-situ sputtering, or to avoid in-situ sputtering, during deposition. Further, in some examples, a higher frequency RF power component may be used to form the plasma, and a lower frequency RF power component may be used to control a rate of in-situ sputtering. Substrate temperature also may be controlled to help control in-situ sputtering. For example, a relatively higher substrate temperature may cause a relatively higher rate of in-situ sputtering. Processing chamber pressure also may be controlled to help control in-situ sputtering. For example, a relatively lower processing chamber pressure may cause a relatively higher rate of in-situ sputtering.

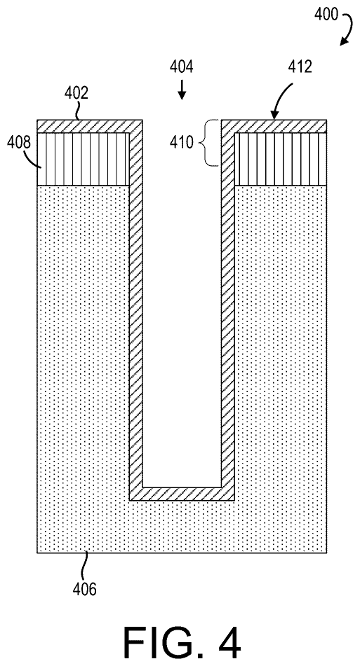

In FIGS. 3A-3B, ALD comprising in-situ sputtering is used to partially fill a gap and form a desired void and dent profile. In other examples, an ALD process comprising in-situ sputtering may be used to form any other suitable angular surface feature. For example, an ALD process comprising in-situ sputtering may be used to form a liner comprising a bevel. FIG. 4 schematically shows a structure 400 comprising a liner deposited using ALD without in-situ sputtering. The liner comprises a film 402 deposited over surfaces of a gap 404 that is formed in a substrate 406. Gap 404 also extends through a layer 408 of silicon oxide disposed on substrate 406. In other examples, layer 408 may comprise any other suitable material, or may be omitted.

Film 402 coats the bottom and sidewalls of gap 404. Film 402 also coats an upper surface of layer 408. In this example, the upper portion 410 of gap 404 near the top of gap 404 may be approximately perpendicular to a surface 412 of layer 408.

Although not depicted in FIG. 4, in some manufacturing processes, it may be desirable to form a bevel in an upper portion of gap 404.

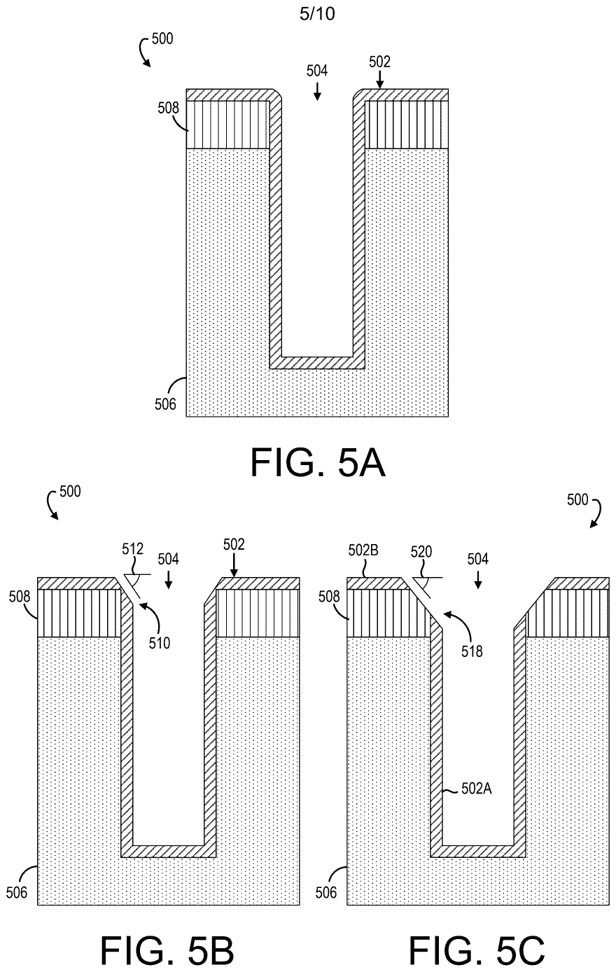

FIGS. 5A-5C schematically show an example deposition of a liner and formation of a bevel using ALD and in-situ sputtering. First, FIG. 5A shows a structure 500 comprising an ALD-deposited liner 502 within a gap 504 in substrate 506. ALD-deposited liner 502 may comprise any suitable film that can be deposited using ALD. Example films include silicon oxide, silicon nitride, silicon oxynitrides, silicon carbides, silicon oxycarbides, and metal oxides. Substrate 506 may represent any suitable structure in which gap 504 may be formed. Examples include a 3D NAND mold stack, a 3D DRAM structure, or a 3D NOR structure. ALD-deposited liner 502 also is deposited over a layer 508 of silicon dioxide. In other examples, layer 508 may comprise any other suitable material, or may be omitted.

FIG. 5B shows a first example endpoint for structure 500 following an in-situ sputtering performed in a PEALD tool after depositing ALD-deposited liner 502 to form a bevel 510 in ALD-deposited liner 502. In FIG. 5B, bevel 510 does not expose layer 508. Bevel 510 comprises a bevel angle 512 that may be based upon a preferential angle of sputtering. A profile of bevel 510 may be controlled by controlling processing conditions such as temperature, pressure, gas composition (including hydrogen gas concentration), and RF power. In some examples, the bevel angle comprises an angle between 45° and 90°. In more specific examples, the bevel angle may comprise an angle between 75° and 89°.

In some examples, a wider opening with a longer bevel surface may be desired. Thus, FIG. 5C schematically shows a second example endpoint for structure 500 structure 500 after further in-situ sputtering. Due to the further sputtering, additional material is removed from ALD-deposited liner 502 to form a bevel 518 in which some material from layer 508 has been removed. As such, a portion of ALD-deposited liner 502A is disposed within gap 504 and a portion of ALD-deposited liner 502B is disposed over layer 508. Bevel 518 comprises a bevel angle 520 that may be based upon a preferential angle of sputtering. A profile of bevel 518 may be controlled by controlling processing conditions such as temperature, pressure, gas composition (including hydrogen gas concentration), and RF power. In some examples, the bevel angle comprises an angle between 45° and 90°. In more specific examples, the bevel angle may comprise an angle between 75° and 89°.

FIGS. 6A-6C show another example deposition of a liner and formation of a bevel using ALD with in-situ sputtering. In the examples of FIGS. 5A-C, the depicted endpoint structures may be formed by in-situ sputtering performed after ALD deposition of a liner. In contrast, the structures of FIGS. 6A-6C are formed using concurrent ALD and in-situ sputtering.

More particularly, FIG. 6A shows a structure 600 comprising a gap 604 in substrate 606 and a layer 608 of silicon dioxide deposited over substrate 606. Substrate 606 may represent any suitable structure in which gap 604 may be formed. Examples include a 3D NAND mold stack, a 3D DRAM structure, or a 3D NOR structure.

FIG. 6B shows structure 600 after performing concurrent ALD and in-situ sputtering. Film 610A, 610B is deposited as a liner over gap 604 and layer 608. Film 610A represents a portion of the film deposited over gap 604. Film 610B represents a portion of the film deposited over layer 608. Further, a bevel 614 is formed by the in-situ sputtering. Film 610A, 610B may comprise any suitable material that can be deposited using ALD. Example films include silicon oxide, silicon nitride, silicon oxynitrides, silicon carbides, silicon oxycarbides, and metal oxides.

FIG. 6C shows structure 600 after further concurrent ALD and in-situ sputtering. Due to additional ALD cycles with in-situ sputtering, film 610A, 610B of FIG. 6C is thicker compared to FIG. 6B. Further, bevel 614 has grown to cover a larger portion of film 610A, 610B. In contrast to the example depicted in FIG. 5C, less, or no, material is removed from layer 608. Bevel 614 comprises a bevel angle 620 that may be based upon a preferential angle of sputtering. A profile of bevel 614 may be controlled by controlling processing conditions such as temperature, pressure, gas composition (including hydrogen gas concentration), and RF power. In some examples, the bevel angle comprises an angle between 45° and 90°. In more specific examples, the bevel angle may comprise an angle between 75° and 89°. In some examples, a mixture of concurrent deposition/sputtering and in-situ sputtering after deposition may be performed to fabricate a desired structure.

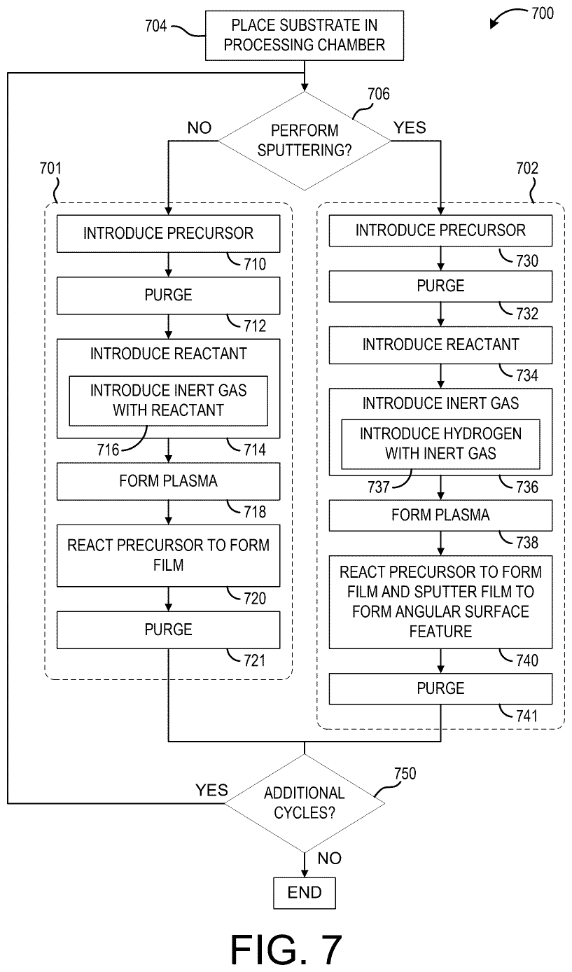

An ALD process comprising in-situ sputtering may be implemented using any suitable sequence of process steps. FIGS. 7, 8, and 9 show example methods 700, 800, and 900 for processing a substrate using ALD comprising in-situ sputtering. Methods 700, 800, and 900 may be performed using any suitable ALD tool configured for plasma processing, such as ALD tool 200.

First, FIG. 7 shows a flow diagram of an example method 700 comprising one or more ALD cycles without sputtering 701, and one or more ALD cycles with sputtering 702. Method 00 comprises, at 704, placing a substrate in a processing chamber of an ALD tool. Method 700 proceeds to 706, where it is determined whether to perform an ALD cycle with sputtering 702 or an ALD cycle without sputtering 701.

If an ALD film deposition without sputtering 701 is to be performed, method 700 proceeds to 710. At 710, ALD cycle without sputtering 701 comprises introducing one or more film precursors into the processing chamber to adsorb the one or more film precursors on the substrate. Suitable film precursors include one or more of silicon-containing precursors, molybdenum-containing precursors, tungsten-containing precursors, aluminum-containing precursors, titanium-containing precursors, tin-containing precursors, zirconium-containing precursors, or hafnium-containing precursors.

ALD cycle without sputtering 701 further comprises, at 712, purging the processing chamber. A purge may be performed to remove excess film precursor from the processing chamber. In some examples, purging at 712 may be omitted. ALD cycle without sputtering 701 further comprises introducing a reactant into the processing chamber at 714. When an oxide film is being deposited, an oxidant may be introduced. In other examples, when a nitride or carbide film is being deposited, a nitrogen-containing reactant or a carbon-containing reactant may be introduced. When an oxynitride film is being deposited, an oxidant and a nitrogen-containing reactant may be introduced. In some examples, nitrogen and oxygen may be introduced in a same molecule (e.g. N₂O). When an oxycarbide film is being deposited, an oxidant and a carbon-containing reactant may be introduced. In some examples, at 716, ALD cycle without sputtering 701 further comprises introducing an inert gas with the reactant. Suitable inert gases include one or more of argon, nitrogen, helium, neon, krypton, or xenon.

ALD cycle without sputtering 701 additionally comprises, at 718, forming a plasma. Any suitable plasma source may be used, such as an inductively coupled plasma generator, a capacitively coupled plasma generator, or a microwave plasma generator. In some examples forming a plasma further may comprise controlling an RF power source of the ALD tool to supply power to a pair of electrodes to form the plasma. Examples of suitable RF power frequencies include 400 kHz, 13.56 MHz, 27 MHz, 60 Mz, and 90 MHz. Examples of suitable powers include powers between 0 and 1500 watts. In some examples, RF power may be supplied at a plurality of different frequencies and/or powers. In some examples, ALD cycle without sputtering 701 may use a relatively higher frequency RF power component at a relatively lower amplitude compared to ALD cycle with sputtering 702.

At 720, ALD cycle without sputtering 701 comprises reacting the reactant with the adsorbed precursors to form a film. In examples where an oxide film is being formed, the plasma may be used to react an oxidant with the adsorbed precursors. In examples where a nitride film is being deposited, the plasma may be used to react a nitrogen-containing reactant with adsorbed precursors. In examples where a carbide film is being deposited, the plasma may be used to react a carbon-containing reactant with adsorbed precursors. In examples where an oxynitride is being formed, the plasma may be used to react an oxidant and a nitrogen-containing reactant with adsorbed precursor. In some examples, a single molecule may provide nitrogen and oxygen (e.g. N₂O). In examples where an oxycarbide is being formed, the plasma may be used to react an oxidant and a carbon-containing reactant with adsorbed precursor. After reacting the precursors using the plasma at 720, the processing chamber is purged at 721.

If it is determined at 706 that an ALD cycle with sputtering 702 is to be performed, method 700 proceeds to 730. At 730, ALD cycle with sputtering 702 comprises introducing one or more film precursors into the processing chamber to adsorb the one or more film precursors on the substrate. ALD cycle with sputtering 702 may then perform an optional purge at 732. In some examples, purging at 732 may be omitted. ALD cycle with sputtering 702 further comprises introducing a reactant into the processing chamber at 734. When an oxide film is being deposited, an oxidant may be introduced. In other examples, when a nitride or carbide film is being deposited, a nitrogen-containing reactant or a carbon-containing reactant may be introduced. When an oxynitride film is being deposited, an oxidant and a nitrogen-containing reactant may be introduced. In some examples, nitrogen and oxygen may be introduced in a same molecule (e.g. N₂O). When an oxycarbide film is being deposited, an oxidant and a carbon-containing reactant may be introduced.

At 736, ALD cycle with sputtering 702 comprises introducing a sputtering gas comprising an inert gas, such as argon, nitrogen, helium, neon, krypton or xenon. In some examples, use of a relatively heavier inert gas may provide for a higher rate of sputtering than a relatively lighter inert gas. For example, using argon at 736 may provide a relatively greater sputtering rate compared to use of helium. In some examples, at 737, ALD cycle with sputtering 702 comprises introducing a hydrogen-containing gas with the inert gas. Examples include hydrogen gas, ammonia, water, methane, or silane. As discussed above, the presence of hydrogen may provide an enhanced sputtering effect. Further, in some examples, the sputtering gas may include a reactant gas for film conversion. Example reactant gases include oxidizing gases, such as molecular oxygen, water vapor, ozone, and hydrogen peroxide.

ALD cycle with sputtering 702 further comprises, at 738, forming a plasma comprising the inert gas. In some examples, the plasma may further comprise reactant introduced at 734 and/or hydrogen introduced at 737. Forming the plasma at 738 may comprise, for example, controlling a RF power source to supply power to a pair of electrodes disposed in the processing chamber. Examples of suitable frequencies include 400 kHz, 13.56 MHz, 27 MHz, 60 Mz, and 90 MHz. Examples of suitable powers include powers between 0 and 1500 watts. In some examples, RF power may be supplied at a plurality of different frequencies and/or powers. In some examples, a first, higher frequency RF power component may be used to form a plasma and a second, lower frequency RF power component may be used to enhance sputtering. Further, in some examples, the ALD cycle with sputtering 702 may utilize a relatively higher amplitude RF power compared to ALD cycle without sputtering 701.

At 740, ALD cycle with sputtering 702 comprises reacting the precursor and reactant using the plasma to form a film on the substrate, and sputtering the film using ions in the plasma to form an angular surface feature. ALD cycle with sputtering 702 further comprises optionally purging the processing chamber at 741.

Processing conditions inside the processing chamber may be controlled in any suitable manner to form a desired angular surface feature using ALD comprising in-situ sputtering. In some examples, a relatively lower pressure may be used when performing ALD cycle with sputtering 702 compared to ALD cycle without sputtering 701. In other examples, ALD cycle without sputtering 701 and ALD cycle with sputtering 702 may be performed at a similar pressure. Example pressures include pressures of 8 Torr or lower. Additionally, the ALD cycles may be performed at any suitable temperature. In some examples, a substrate temperature within a range of 50 °C to 1000 °C may be used. The use of a relatively higher temperature may help achieve a relatively higher sputtering rate. Likewise, a spacing between a substrate support and a processing chemical outlet configured as electrodes may be adjusted to control sputtering rates. In some examples, a spacing may be within a range of 0.2 inches to 0.8 inches. In other examples, a spacing outside this range may be used.

After completing an ALD cycle without sputtering 701 or an ALD cycle with sputtering 702, it is determined at 750 whether additional cycles are to be performed. If yes, method 700 returns to 706. If no, method 700 ends.

Method 700 may comprise any suitable number of and order of ALD cycles without sputtering 701 and ALD cycles with sputtering 702. The use of a greater number of ALD cycles may deposit a thicker film than the use of a lesser number of ALD cycles. Further, performing a relatively greater proportion of ALD cycles with sputtering 702 may provide a relatively greater sputtering effect on the film. In some examples, the ratio of ALD cycles without sputtering 701 to ALD cycles with sputtering 702 may be within a range of 1:20 to 20:1. In various examples, the ratio of ALD cycles without sputtering 701 to ALD cycles with sputtering 702 may be adjusted to achieve a selected profile of an angular surface feature, such as a selected dent depth, a selected dent angle, or a selected bevel angle.

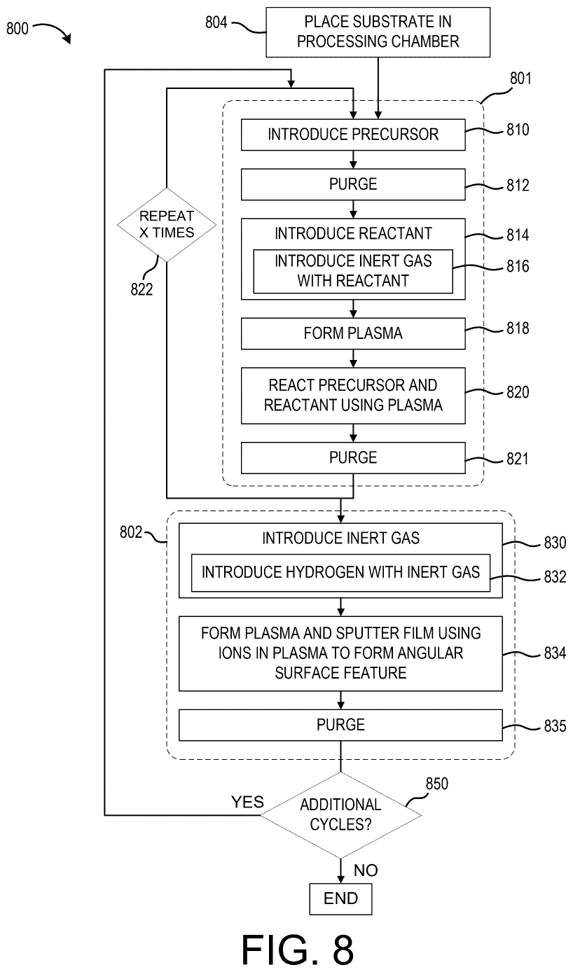

FIG. 8 shows a flow diagram of another example method 800 for performing ALD comprising in-situ sputtering. In contrast with method 700, method 800 comprises ALD cycles without sputtering 801, and separate sputtering cycles 802 without deposition. At 804, method 800 comprises placing a substrate into a processing chamber of a processing tool. Method 800 further comprises performing one or more ALD cycles without sputtering 801 to deposit a film on the substrate.

At 810, ALD cycle without sputtering 801 comprises introducing one or more film precursors into the processing chamber to adsorb the one or more film precursors on the substrate. Suitable films include films of silicon oxide, silicon nitride, silicon oxynitride, silicon carbides, silicon oxycarbides, and metal oxides. Any suitable precursor or combination of precursors may be used, such as those discussed above. ALD cycle without sputtering 801 further comprises, at 812, purging the processing chamber. In some examples, purging at 812 may be omitted. At 814, method 800 comprises introducing a reactant into the processing chamber. When an oxide film is being deposited, an oxidant may be introduced. When a nitride or carbide film is being deposited, a nitrogen-containing reactant or a carbon-containing reactant may be introduced. When an oxynitride film is being deposited, an oxidant and a nitrogen-containing reactant may be introduced. In some examples, nitrogen and oxygen may be introduced in a same molecule (e.g. N₂O). When an oxycarbide film is being deposited, an oxidant and a carbon-containing reactant may be introduced. In some examples, at 816, ALD cycle without sputtering 801 further comprises introducing an inert gas with the reactant. Suitable inert gases include argon, nitrogen, helium, neon, krypton and xenon. ALD cycle without sputtering 801 additionally comprises, at 818, forming a plasma. At 820, ALD cycle without sputtering 801 comprises reacting the one or more film precursors and reactant to form a layer of film on the substrate. After reacting the precursors with the reactant using the plasma at 820, the processing chamber is purged at 821.

As indicated at 822, ALD cycle without sputtering 801 may be repeated any suitable number “X” of times. After performing the one or more ALD cycles without sputtering 801, method 800 proceeds to 830 and performs a sputtering cycle 802. Sputtering cycle 802 allows in-situ sputtering to be performed on a film separately from an ALD cycle without sputtering 801. Any suitable sputtering gas may be used. At 830, method 800 comprises introducing an inert gas into the processing chamber for use as a sputtering gas. Any suitable inert gas may be used, such as argon, nitrogen, helium, neon, krypton or xenon. In some examples, at 832, sputtering cycle 802 comprises introducing a hydrogen-containing gas with the inert gas. As described above, presence of hydrogen may help achieve a relatively greater sputtering rate compared to examples that omit hydrogen. Further, in some examples, the sputtering gas may include a reactant gas for film conversion. Example reactant gases include oxidizing gases, such as molecular oxygen, water vapor, ozone, and hydrogen peroxide.

Continuing, sputtering cycle 802 further comprises, at 834, forming a plasma and sputtering the film using ions in the plasma to form an angular surface feature in the film. Forming the plasma at 834 may comprise controlling a RF power source to supply power to a pair of electrodes disposed in the processing chamber. Examples of suitable frequencies include 400 kHz, 13.56 MHz, 27 MHz, 60 Mz, and 90 MHz. Examples of suitable powers include powers between 0 and 1500 watts. As described above, RF power may be supplied at a plurality of different frequencies and/or powers. In some examples, sputtering cycle 802 may use a high frequency RF power component at a relatively higher amplitude to form the plasma at 834 compared to ALD cycle without sputtering 801. Further, sputtering cycle 802 may use low frequency RF power component in combination with a high frequency RF power component. As described above, a relatively amplitude and/or use of a low frequency RF power component may help increase a rate of sputtering during sputtering cycle 802. After extinguishing the plasma, sputtering cycle 802 optionally comprises purging the processing chamber at 835.

Conditions inside the processing chamber may be adjusted to control the amount of sputtering during sputtering cycle 802. In some examples, performing sputtering cycle 802 at a relatively lower pressure may help achieve a relatively greater sputtering rate at 834. In some examples, sputtering cycle 802 may be performed while maintaining a pressure that is 8 Torr or lower. In other examples, any other suitable pressure may be used. In some examples, a relatively lower pressure may be used when performing sputtering cycle 802 compared to ALD cycle without sputtering 801. In some examples, ALD cycle without sputtering 801 and sputtering cycle 802 may be performed at a similar pressure. Additionally, sputtering cycle 802 may be performed at any suitable temperature. In some examples, a substrate temperature within a range of 50 °C to 1000 °C may be used. In some examples, use of a relatively higher temperature may help achieve a relatively greater sputtering rate at 834. Further, a spacing between processing chemical outlet and the substrate support electrodes may be adjusted. In some examples, a spacing may be within a range of 0.2 inches to 0.8 inches. In other examples, a spacing outside this range may be used. A relatively smaller spacing may help achieve a relatively greater sputtering rate at 834 compared to a relatively larger spacing.

Any suitable duration of sputtering may be used at 834. In some examples, sputtering cycle 802 may comprise a sputter duration within a range of 10 seconds to 200 seconds. In other examples, durations outside of this range may be used.

In some examples, a final sputtering cycle (e.g., sputtering cycle 802) may be performed to modify a profile of an angular surface feature. For example, a plurality of ALD cycles without sputtering 801 followed by sputtering cycles 802 may be used to deposit a film over a gap and form an angular surface feature in the film. Then, a final sputtering cycle may be performed to modify the angular surface feature. In the specific example of a dent, a final sputtering cycle may be used to modify a dent angle of the dent and/or form a rounder dent. In some examples, performing a final sputtering cycle may help achieve a relatively wider dent angle. In some examples, a dent angle may comprise an angle ≥60°. In some examples, a final sputtering cycle may be used to increase a dent angle to ≥80°, ≥90°, or ≥95°.

After completing a sputtering cycle 802, method 800 proceeds to 850 and determines if additional cycles are to be performed. If “YES”, method 800 returns to 810 and begins an ALD cycle without sputtering 801. If no additional cycles are to be performed, then method 800 ends.

Method 800 may comprise any suitable number of ALD cycles without sputtering 801 and sputtering cycles 802. Performing a greater number of ALD cycles without sputtering 801 may help deposit a relatively thicker film. Further, the ratio of ALD cycles without sputtering 801 to sputtering cycles 802 may be adjusted to achieve a selected degree of sputtering. In various examples, the ratio of ALD cycles without sputtering 801 to sputtering cycles 802 may be within a range of 1:1 to 1:20, within a range of 1:1 to 1:100, within a range of 1:1 to 1:1000, or within a range of 1:1 to 1:5000. The ratio of ALD cycles without sputtering 801 to sputtering cycles 802 and/or a sputter duration of sputtering cycles 802 may be adjusted to achieve a selected profile of an angular surface feature. Examples include a selected dent depth, a selected dent angle, or a selected bevel angle.

FIG. 9 shows a flow diagram of an example method 900 for performing ALD cycles without sputtering 901, ALD cycles 902 with sputtering, and sputtering cycles 903 separate from ALD cycles. At 902, method 900 comprises placing a substrate in a processing chamber of an ALD tool configured to perform sputtering.

Method 900 comprises, at 904, placing a substrate in a processing chamber of an ALD tool. Method 900 then proceeds to 906, where it is determined whether to perform an ALD cycle with sputtering 902 or an ALD cycle without sputtering 901. As discussed above, ALD cycles may be performed to deposit any suitable film on a substrate. Suitable films include films of silicon oxide, silicon nitride, silicon oxynitride, silicon carbides, silicon oxycarbides, and metal oxides. Any suitable precursor or combination of precursors may be used, such as those discussed above.

ALD cycle without sputtering 901 is equivalent to ALD cycle without sputtering 801 and ALD cycle without sputtering 701. At 910, ALD cycle without sputtering 901 comprises introducing one or more film precursors into the processing chamber to adsorb the one or more film precursors on the substrate. ALD cycle without sputtering 901 further comprises, at 912, purging the processing chamber. In some examples, purging at 912 may be omitted. ALD cycle without sputtering 901 further comprises introducing a reactant into the processing chamber at 914. When an oxide film is being deposited, an oxidant may be introduced. In other examples, when a nitride or carbide film is being deposited, a nitrogen-containing reactant or a carbon-containing reactant may be introduced. When an oxynitride film is being deposited, an oxidant and a nitrogen-containing reactant may be introduced. In some examples, nitrogen and oxygen may be introduced in a same molecule (e.g. N₂O). When an oxycarbide film is being deposited, an oxidant and a carbon-containing reactant may be introduced. In some examples, at 916, ALD cycle without sputtering 901 further comprises introducing an inert gas with the reactant. ALD cycle without sputtering 901 additionally comprises, at 918, forming a plasma. At 920, ALD cycle without sputtering 901 comprises reacting the one or more film precursors with the reactant to form a layer of film on the substrate. After reacting the precursors with the reactant using the plasma at 920, the processing chamber may be optionally purged at 921.

On the other hand, if, at 906, it is determined that an ALD cycle with sputtering 902 is to be performed, method 900 proceeds to 930. At 930, ALD cycle with sputtering 902 comprises introducing one or more film precursors into the processing chamber to adsorb the one or more film precursors on the substrate. ALD cycle with sputtering 902 may then perform an optional purge at 932. At 934, method 900 comprises introducing a reactant into the processing chamber. When an oxide film is being deposited, an oxidant may be introduced. When a nitride or carbide film is being deposited, a nitrogen-containing reactant or a carbon-containing reactant may be introduced. When an oxynitride film is being deposited, an oxidant and a nitrogen-containing reactant may be introduced. In some examples, nitrogen and oxygen may be introduced in a same molecule (e.g. N₂O). When an oxycarbide film is being deposited, an oxidant and a carbon-containing reactant may be introduced.

At 936, ALD cycle with sputtering 902 comprises introducing a sputtering gas comprising an inert gas. In some examples, at 937, ALD cycle with sputtering 902 comprises introducing a hydrogen-containing gas with the inert gas. As discussed above, the presence of hydrogen may provide an enhanced sputtering effect. Further, in some examples, the sputtering gas may include a reactant gas for film conversion. Example reactant gases include oxidizing gases, such as molecular oxygen, water vapor, ozone, and hydrogen peroxide. ALD cycle with sputtering 902 further comprises, at 938, forming a plasma comprising the inert gas. At 940, ALD cycle with sputtering 902 comprises reacting the precursor with the reactant using the plasma to form a film on the substrate, and sputtering the film using ions in the plasma to form an angular surface feature. ALD cycle with sputtering 902 further comprises optionally purging the processing chamber at 941.

As indicated at 942, ALD cycles may be repeated any suitable number of times. Further, ALD cycle without sputtering 901 and ALD cycle with sputtering 902 may be performed in any suitable order.

After performing a suitable number of ALD cycles, method 900 may proceed from 942 to 950 and perform a sputtering cycle 903. Sputtering cycle 903 may be equivalent to sputtering cycle 802. At 950, sputtering cycle 903 comprises introducing a sputtering gas comprising an inert gas into the processing chamber. In some examples, at 952, sputtering cycle 903 comprises introducing a hydrogen-containing gas with the inert gas. Further, in some examples, the sputtering gas may include a reactant gas for film conversion. Sputtering cycle 903 further comprises, at 954, forming a plasma and sputtering the film using ions in the plasma to form an angular surface feature in the film. After extinguishing the plasma, sputtering cycle 903 comprises optionally purging the processing chamber at 955.

After completing a sputtering cycle 903, method 900 proceeds to 960 and it is determined whether to perform additional ALD cycles. If “YES”, method 900 returns to 906 and it is determined whether to perform an ALD cycle without sputtering 901 or an ALD cycle with sputtering 902. If no additional cycles are to be performed, the method ends.

As discussed above, conditions inside the processing chamber may be adjusted to control the amount of sputtering during ALD cycle with sputtering 902 and sputtering cycle 903. In some examples, a relatively lower pressure may help achieve a relatively greater sputtering rate at 940 and/or at 954. In some examples, sputtering may be performed while maintaining a pressure of 8 Torr or lower. In other examples, any other suitable pressure may be used. In some examples, a relatively lower pressure may be used when performing ALD cycle with sputtering 902 or sputtering cycle 903 compared to ALD cycle without sputtering 901. Additionally, method 900 may be performed at any suitable temperature. In some examples, a substrate temperature within a range of 50 °C to 1000 °C may be used. In some examples, use of a relatively higher temperature may help achieve a relatively greater sputtering rate at 940 and/or at 954. Further, a spacing between a processing chemical outlet and a substrate support may be adjusted where a relatively smaller spacing may help achieve a relatively greater sputtering rate compared to a larger spacing. In some examples, a spacing may be within a range of 0.2 inches to 0.8 inches. In other examples, a spacing outside this range may be used.

Forming a plasma at 920, at 940, and at 954 may comprise controlling a RF power source to supply power at any suitable frequency and any suitable power. Examples of suitable frequencies include 400 kHz, 13.56 MHz, 27 MHz, 60 Mz, and 90 MHz. Examples of suitable powers include powers between 0 and 1500 watts. As described above, RF power may be supplied at a plurality of different frequencies and/or powers. In some examples, ALD cycle with sputtering 902 and sputtering cycle 903 each may use a high frequency RF power component at a relatively higher amplitude to form a plasma compared to ALD cycle without sputtering 901. Further, ALD cycle with sputtering 902 and sputtering cycle 903 each may optionally use a low frequency RF power component in combination with a high frequency RF power component. As described above, a relatively higher amplitude and/or use of a low frequency RF power component may help enhance in-situ sputtering.

In some examples, sputtering the film at 940 and at 954 comprises forming a dent above a void. In some examples, sputtering may help lower a closure depth of a void and increase a thickness of a film portion above the void. In some examples, sputtering may comprise forming a bevel in a liner coating a gap. In some examples, a final sputtering cycle (e.g., a sputtering cycle 903) may be performed to modify a profile of an angular surface feature. For example, repeated ALD cycles without sputtering 901 and ALD cycles with sputtering 902 may be used to deposit a film over a gap and form a dent in the film. Then, a sputtering cycle 903 may be performed to modify a dent angle of the dent and/or form a rounder dent. In some examples, performing a final sputtering cycle may help achieve a relatively wider dent angle. In some examples, a dent angle may comprise an angle ≥60°. In some examples, a final sputtering cycle may be used to increase a dent angle to ≥80°, ≥90°, or ≥95°.

Thus, the disclosed examples may help achieve in-situ sputtering within an ALD tool to form an angular substrate feature. Performing in-situ sputtering and film deposition in an ALD tool may allow a film to partially fill a gap while avoiding the formation of a sharp dent angle, and while pushing a pinch-off depth to a suitable depth in the gap for later processing. Performing in-situ sputtering in an ALD tool also may allow other angular surface features to be formed, such as a beveled liner formed within a gap. Such structures may be formed without moving a substrate repeatedly between an ALD tool and a sputtering tool. This may allow the disclosed examples of angular surface features to be efficiently formed in an ALD tool.

In some embodiments, the methods and processes described herein may be tied to a computing system of one or more computing devices. In particular, such methods and processes may be implemented as a computer-application program or service, an application-programming interface (API), a library, and/or other computer-program product.

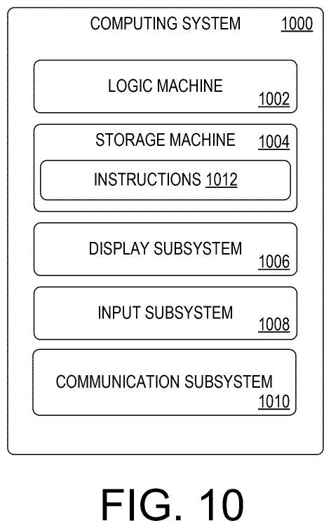

FIG. 10 schematically shows a non-limiting embodiment of a computing system 1000 that can enact one or more of the methods and processes described above. Computing system 1000 is shown in simplified form. Computing system 1000 may take the form of one or more personal computers, workstations, computers integrated with substrate processing tools, and/or network accessible server computers.

Computing system 1000 includes a logic machine 1002 and a storage machine 1004. Computing system 1000 may optionally include a display subsystem 1006, input subsystem 1008, communication subsystem 1010, and/or other components not shown in FIG. 10. Controller 230 is an example of computing system 1000.

Logic machine 1002 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1004 includes one or more physical devices configured to hold instructions 1012 executable by the logic machine to implement the methods and processes described herein. When such methods and processes are implemented, the state of storage machine 1004 may be transformed—e.g., to hold different data.

Storage machine 1004 may include removable and/or built-in devices. Storage machine 1004 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1004 may include volatile, nonvolatile, dynamic, static, read/write, read-only, random-access, sequential-access, location-addressable, file-addressable, and/or content-addressable devices.

It will be appreciated that storage machine 1004 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1002 and storage machine 1004 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1006 may be used to present a visual representation of data held by storage machine 1004. This visual representation may take the form of a graphical user interface (GUI). As the herein described methods and processes change the data held by the storage machine, and thus transform the state of the storage machine, the state of display subsystem 1006 may likewise be transformed to visually represent changes in the underlying data. Display subsystem 1006 may include one or more display devices utilizing virtually any type of technology. Such display devices may be combined with logic machine 1002 and/or storage machine 1004 in a shared enclosure, or such display devices may be peripheral display devices.

When included, input subsystem 1008 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 1010 may be configured to communicatively couple computing system 1000 with one or more other computing devices. Communication subsystem 1010 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 1000 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. In an integrated circuit manufacturing process, a method of forming an angular surface feature on a substrate, the method comprising:
placing the substrate in a processing chamber of an atomic layer deposition (ALD) tool;
controlling the ALD tool to form a film on the substrate by performing one or more ALD cycles; and
controlling the ALD tool to sputter the film to form the angular surface feature.

2. The method of claim 1, wherein an ALD cycle of the one or more ALD cycles comprises
introducing a film precursor into the processing chamber to adsorb the film precursor on the substrate,
purging the processing chamber,
introducing an oxidant into the processing chamber, and
reacting the film precursor and the oxidant by forming a plasma comprising the oxidant to form the film.

3. The method of claim 2, wherein controlling the ALD tool to sputter the film comprises sputtering the film within the ALD cycle using ions in the plasma.

4. The method of claim 3, further comprising controlling the ALD tool to form the plasma using a lower frequency component and a higher frequency component.

5. The method of claim 2, wherein the controlling the ALD tool to sputter the film comprises performing a sputtering cycle in the ALD tool separate from the one or more ALD cycles.

6. The method of claim 1, wherein the angular surface feature comprises a dent above a void.

7. The method of claim 1, wherein the angular surface feature comprises a bevel in a liner of a gap.

8. The method of claim 1, wherein controlling the ALD tool to sputter the film comprises forming a plasma comprising an inert gas and hydrogen.

9. The method of claim 1, wherein controlling the ALD tool to sputter the film comprises controlling the processing tool to heat a substrate heater to a temperature within a range of 50 °C to 1000 °C.

10. The method of claim 1, wherein controlling the ALD tool to sputter the film comprises controlling the ALD tool to maintain a pressure of 8 Torr or lower in the processing chamber during sputtering.

11. An atomic layer deposition (ALD) tool, comprising:
a processing chamber;
a substrate support disposed in the processing chamber;
a film precursor source comprising a film precursor;
a reactant gas source comprising a reactant;
an inert gas source comprising an inert gas;
flow control hardware configured to control flows of film precursor, reactant, and inert gas into the processing chamber;
a radiofrequency power source operable to form a plasma in the processing chamber; and
a controller configured to
control the flow control hardware and the radiofrequency power source to perform one or more ALD cycles to form a film on a substrate placed on the substrate support, and
control the flow control hardware and the radiofrequency power source to perform one or more sputtering cycles to sputter the film to form an angular surface feature, the one or more sputtering cycles being separate from the one or more ALD cycles.

12. The ALD tool of claim 11, further comprising a hydrogen gas source comprising hydrogen gas, wherein the controller is further configured to control the flow control hardware to introduce the inert gas and the hydrogen gas into the processing chamber, and control the radiofrequency power source to form a plasma comprising the inert gas and the hydrogen gas.

13. The ALD tool of claim 11, wherein the radiofrequency power source is configured to supply radiofrequency power comprising a lower frequency component and a higher frequency component.

14. The ALD tool of claim 11, further comprising an exhaust system, wherein the controller is further configured to control the flow control hardware and the exhaust system to maintain a pressure inside the processing chamber of 8 Torr or lower during the one or more sputtering cycles.

15. The ALD tool of claim 11, wherein the controller is further configured to sputter the film during at least one ALD cycle of the one or more ALD cycles.

16. (canceled)

17. The ALD tool of claim 11, wherein the controller further configured to purge the chamber after controlling the radiofrequency power source to extinguish the plasma.

18. The ALD tool of claim 11, wherein the flow control hardware is configured to introduce the inert gas into the processing chamber through a processing chemical outlet, the processing chemical outlet being separated from the substrate by a spacing within a range of 0.2 inches to 0.8 inches.

19. An atomic layer deposition (ALD) tool, comprising:
a processing chamber;
a substrate support disposed in the processing chamber;
one or more film precursor sources comprising one or more film precursors;
one or more reactant sources comprising one or more reactants;
an inert gas source comprising an inert gas;
flow control hardware configured to control flows of the one or more film precursors, the one or more reactants, and the inert gas into the processing chamber;
a radiofrequency power source and an electrode pair configured to form a plasma in the processing chamber; and
a controller configured to
control the flow control hardware and the radiofrequency power source to perform one or more ALD cycles with sputtering to form a film on a substrate placed on the substrate support and to form an angular surface feature of the film.

20. The ALD tool of claim 19, wherein the one or more reactants comprises a nitrogen-containing precursor.

21. The ALD tool of claim 19, wherein the one or more reactants comprises an oxidant.
